(19) United States
(12) Patent Application Publication
(10) Pub. No.: US 2025/0391628 A1
(43) Pub. Date: Dec. 25, 2025

(54) CALIBRATION OF DIGITAL ANALOG CONVERTER TO CONTROL DEFLECTORS IN CHARGED PARTICLE BEAM SYSTEM

(71) Applicant: ASML Netherlands B.V., Veldhoven (NL)

(72) Inventors: Kuo-Chin CHIEN, San Jose, CA (US); Jie MA, San Jose, CA (US)

(73) Assignee: ASML Netherlands B.V., Veldhoven (NL)

(21) Appl. No.: 18/878,597

(22) PCT Filed: Jun. 20, 2023
(86) PCT No.: PCT/EP2023/066712

§ 371 Date: Dec. 23, 2024

Related U.S. Application Data
(60) Provisional application No. 63/356,757, filed on Jun. 29, 2022.

(51) Int. Cl. H01J 37/147; H01J 37/28; H03M 1/66

(52) U.S. Cl. CPC H01J 37/1474; H01J 37/28; H03M 1/66; H01J 2237/1504

(57) ABSTRACT

A method for controlling deflectors of a charged-particle inspection system is disclosed. The method comprises establishing a mapping relationship for each digital-to-analog converter (DAC) of a plurality of DACs included in a charged-particle inspection system, the mapping relationship characterizing non-linearity behavior of each of the DACs, determining target control signals for manipulating deflectors of the charged-particle inspection system, determining, for each DAC of the plurality of DACs, an error correcting digital input based on a corresponding target control signal among the target control signals and the corresponding mapping relationship, and inputting the corresponding error correcting digital input to each of the DACs to enable each of the DACs to generate a corresponding error compensated output.

### CROSS-REFERENCE TO RELATED APPLICATIONS

This application claims priority of U.S. application No. 63/356,757 which was filed on Jun. 29, 2022. and which is incorporated herein in its entirety by reference.

### TECHNICAL FIELD

The embodiments provided herein generally relate to an inspection apparatus, and more particularly, to a charged particle beam manipulation system of an inspection apparatus.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, defect detection accuracy becomes more important. Accordingly, precise manipulation of deflectors to guide charged particle beams to targeted positions on a sample has become critical to meet the higher demand for accurate inspection and metrology.

### SUMMARY

Some embodiments provide a method for controlling deflectors of a charged-particle inspection system. The method can comprise establishing a mapping relationship for each digital-to-analog converter (DAC) of a plurality of DACs included in a charged-particle inspection system, the mapping relationship characterizing non-linearity behavior of each of the DACs; determining target control signals for manipulating deflectors of the charged-particle inspection system; determining, for each DAC of the plurality of DACs, an error correcting digital input based on a corresponding target control signal among the target control signals and the corresponding mapping relationship; and inputting the corresponding error correcting digital input to the each DAC to enable the each DAC to generate a corresponding error compensated output.

Some embodiments provide a charged-particle inspection apparatus. The apparatus can comprise a charged-particle beam source configured to generate a primary charged-particle beam for sample scanning; a plurality of deflector electrodes configured to influence the charged particle beam; and a controller configured to control the plurality of deflector electrodes, wherein the controller is configured to perform: determining target control signals for controlling the plurality of deflector electrodes, the plurality of deflector electrodes associated with a plurality of DACs; determining, for each DAC of the plurality of DACs, an error correcting digital input based on a corresponding target control signal among the target control signals and a corresponding mapping relationship among a plurality of mapping relationships each representing non-linearity behavior of each of the DACs; and inputting the corresponding error correcting digital input to the each DAC to enable the each DAC to generate a corresponding error compensated output.

Some embodiments provide a non-transitory computer readable medium including a set of instructions that is executable by one or more processors of a controller to cause the controller to perform a method for controlling deflectors of a charged-particle inspection system. The method can comprise determining target control signals for manipulating a plurality of deflector electrodes, the plurality of deflector electrodes associated with a plurality of DACs; determining, for each DAC of the plurality of DACs, an error correcting digital input based on a corresponding target control signal among the target control signals and a corresponding mapping relationship among a plurality of mapping relationships each representing non-linearity behavior of each of the DACs; and inputting the corresponding error correcting digital input to the each DAC to enable the each DAC to generate a corresponding error compensated output.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an exemplary charged-particle beam inspection system, consistent with embodiments of the present disclosure.

FIG. 2A is a schematic diagram illustrating an exemplary multi-beam tool, consistent with embodiments of the present disclosure that can be a part of the exemplary charged-particle beam inspection system of FIG. 1.

FIG. 2B is a schematic diagram illustrating an exemplary single-beam tool, consistent with embodiments of the present disclosure that can be a part of the exemplary charged-particle beam inspection system of FIG. 1.

FIG. 3A is a diagram illustrating a configuration of a scanning deflection system, consistent with embodiments of the present disclosure.

FIG. 3B is a diagrammatic representation of deflection of a charged particle beam, consistent with embodiments of the present disclosure.

FIG. 3C is a diagram illustrating a configuration of exemplary deflection elements, consistent with embodiments of the present disclosure.

FIG. 4 is a schematic diagram illustrating an exemplary configuration of a deflection control unit associated with charged-particle beam deflectors, consistent with embodiments of the present disclosure.

FIG. 5 is a graph illustrating distortions introduced by digital-to-analog converters (DACs) of a deflection control unit associated with charged-particle beam deflectors.

FIG. 6 is a flow chart illustrating an exemplary method for generating a lookup table for characterizing a DAC of a deflection control unit associated with charged-particle beam deflectors, consistent with embodiments of the present disclosure.

FIG. 7A is a schematic diagram illustrating a test environment for characterizing a DAC, consistent with embodiments of the present disclosure.

FIG. 7B is an example lookup table characterizing a DAC of a deflection control unit, consistent with embodiments of the present disclosure.

FIG. 7C is another example lookup table characterizing a DAC of a deflection control unit, consistent with embodiments of the present disclosure.

FIG. 8 is a flow chart illustrating an exemplary method for controlling deflectors, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

As the physical sizes of IC components continue to shrink, defect detection accuracy becomes more important. Accordingly, precise manipulation of deflectors to guide charged particle beams to targeted positions on a sample has become critical to meet the higher demand for accurate inspection and metrology. Control signals to manipulate deflectors can be precisely calculated and then supplied to the deflectors after being converted to analog signal by digital-to-analog converters (DACs). However, errors in designing, or variances in manufacturing or fabricating a DAC may cause a DAC analog signal output to deviate from an intended analog value. This may result in a beam scanning a wrong position on a sample and thus causing an error on a resultant inspection image. In some embodiments, a plurality of DACs in one inspection system can be implemented to have the same architecture and design. However, each DAC's behavior can differ from the other DACs due to manufacturing process variances. For example, DACs having the same design and architecture can output differing values from a same digital input depending on the corresponding process variances such as under-etching, over-etching, process errors, etc.

In order to correct or calibrate errors introduced by DACs associated with deflectors of a SEM tool, various efforts have been made. First, a linear calibration method has been applied to correct error(s) of DACs. The linear calibration method comprises a gain or offset calibration through a digital circuit or an analog circuit. In some instances, the linear calibration can be performed either via hardware or software. However, the linear calibration may correct linear errors caused by DACs but does not correct non-linear distortions introduced by DACs. Therefore, the error correcting performance of the linear calibration method may be limited as this method only addresses linear distortions.

In order to correct non-linearity errors caused by DACs, an error correction method based on an inspection image has been conventionally utilized. In the error correction method based on an inspection image, the inspection image is compared to a reference image. When there is a mismatch between the reference image and the inspection image, it can be presumed that the mismatch originates from DACs errors. Thereby, the inspection image-based correction method calibrates digital inputs to the DACs to correct the error (e.g., to remove the mismatch) on an inspection image going forward. However, it has been reported that the inspection image-based error correction method often suffers from over corrections by calibrating deflection inputs to the DACs even when the error(s) on the inspection image does not originate from errors on the DACs. For example, the inspection image-based error correction method may adjust deflection inputs to calibrate out errors caused by wafer process, which may cause more errors on an inspection image due to overcorrection. Further, although the inspection image-based error correction method can contribute to non-linearity error corrections, the method only applies to calibrations generic to all DACs of one inspection system. In other words, the conventional method could not address error(s) specific to each DAC. As the inspection image-based calibration is performed per hardware design/setting, the time-consuming calibration process repeats for all use cases (e.g., separate calibration for each hardware design/setting), which wastes resources of the inspection system and degrades inefficiency. Moreover, calibration of the conventional error correction method is performed after an inspection image is generated using the inspection system with DACs, which requires longer initialization time and thus worsens resource waste of the inspection system.

The conventional method could meet the industry accuracy criteria in the past. However, the demand for more accurate inspection systems is ever increasing as the physical sizes of IC components continue to shrink and defect detection accuracy becomes more important. Therefore, methods and systems that can more accurately and precisely manipulate deflectors are thus desired.

According to some embodiments of the present disclosure, each DAC's behavior can be individually characterized, and a lookup table for each DAC can be established. According to some embodiments, a lookup table for each DAC can be utilized to control deflectors. According to some embodiments of the present disclosure, calibration to each DAC can be performed before the inspection system is launched for inspection, and thus resource waste can be avoided and system initialization time can be saved.

Relative dimensions of components in drawings may be exaggerated for clarity. Within the following description of drawings, the same or like reference numbers refer to the same or like components or entities, and only the differences with respect to the individual embodiments are described. Other objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing scanning deflection systems and scanning deflection methods in systems utilizing electron beams (“e-beams”). Some scanning deflection systems may use electric fields to influence a charged particle beam. However, the disclosure is not so limited. Other types of charged particle beams may be similarly applied. For example, systems and methods may be applicable with optics, photons, x-rays, and ions, etc. Deflection may be used to scan a beam over a surface in, for example, cathode ray tubes (CRTs), lithography machines, scanning electron microscopes (SEMs), or other analytical instruments. While some embodiments are discussed with reference to deflection systems that use electric field to influence a beam, deflection may also be achieved with magnetic fields, for example.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

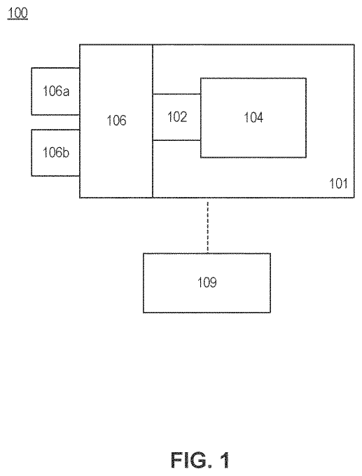

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

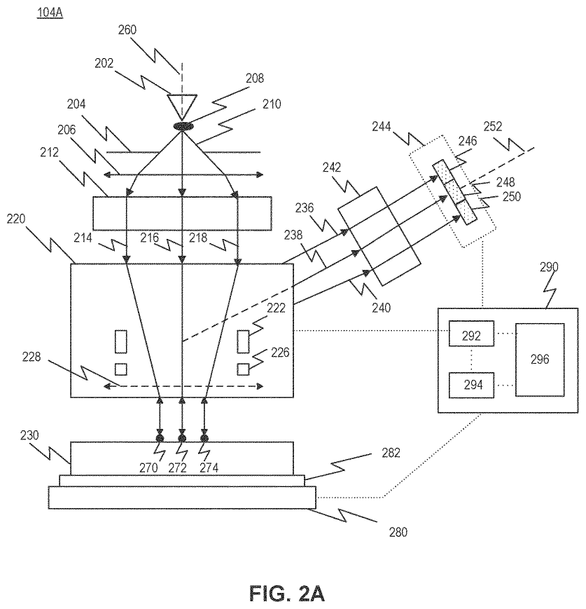

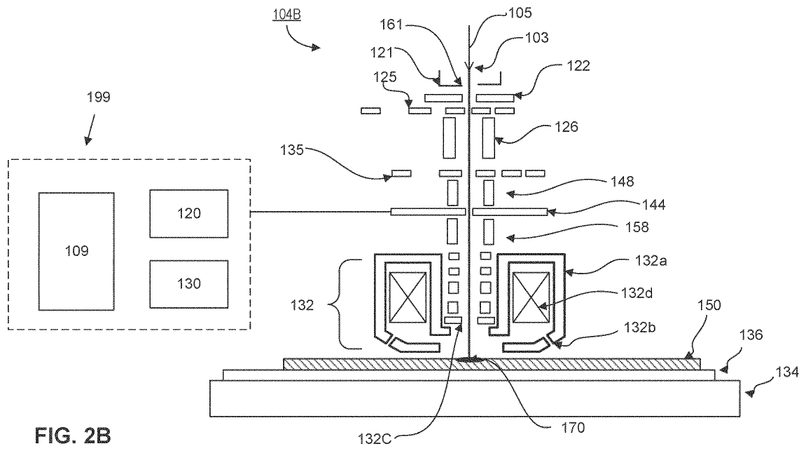

FIG. 2A illustrates a schematic diagram of an exemplary multi-beam beam tool 104A (also referred to herein as apparatus 104A) and an image processing system 290 that may be configured for use in EBI system 100 (FIG. 1), consistent with embodiments of the present disclosure.

Beam tool 104A comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104A. Secondary optical system 242 and charged-particle detection device 244 can be aligned with a secondary optical axis 252 of apparatus 104A.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2A, embodiments of the present disclosure are not so limited. For example, in some embodiments, the apparatus 104A may be configured to generate a first number of beamlets. In some embodiments, the first number of beamlets may be in a range from 1 to 1000. In some embodiments, the first number of beamlets may be in a range from 200-500. In an exemplary embodiment, an apparatus 104A may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104A through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2A). The quantity of BSEs and SEs may be more or fewer (or even the same) than the injected electrons of primary charged-particle beam 210.

Another example of a charged particle beam apparatus will now be discussed with reference to FIG. 2B. Beam tool 104B (also referred to herein as apparatus 104B) may be an example of beam tool 104 and may be similar to beam tool 104A shown in FIG. 2A. However, different from apparatus 104A, apparatus 104B may be a single-beam tool that uses only one primary electron beam to scan one location on the wafer at a time.

As shown in FIG. 2B, apparatus 104B includes a wafer holder 136 supported by motorized stage 134 to hold a wafer 150 to be inspected. Beam tool 104B includes an electron emitter, which may comprise a cathode 103, an anode 121, and a gun aperture 122. Beam tool 104B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector unit 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector unit 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of beam tool 104B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 104B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2B, discussed above, a beam separator 222 may be provided to direct secondary electron beams toward a detector placed off-axis. Beam separator 222 may be configured to divert secondary electron beams toward an electron detection device 244, as shown in FIG. 2A.

The images generated by SEM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

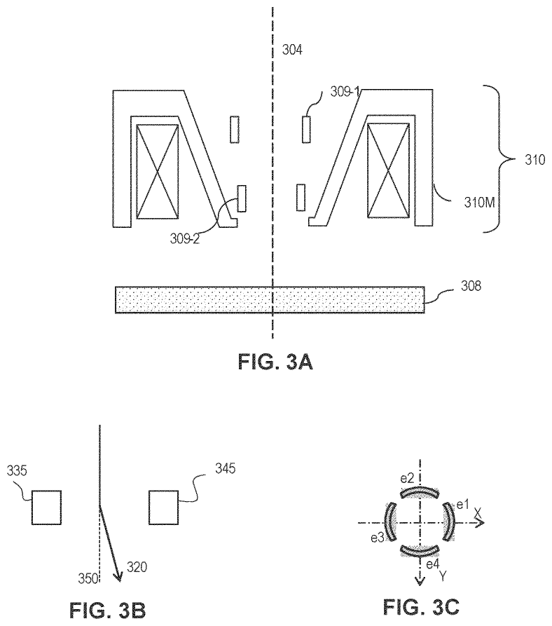

Reference is now made to FIG. 3A, which illustrates configuration of deflectors and objective lens assembly, consistent with embodiments of the present disclosure. As shown in FIG. 3A, deflectors 309-1 and 309-2 may be disposed within the magnetic field of a magnetic objective lens assembly 310, wherein deflectors 309-1 and 309-2 may be implemented in a deflection scanning unit (e.g., deflection scanning unit 226 of FIG. 2A) or as a deflector unit (e.g., deflector unit 132c of FIG. 2B). Deflectors 309-1 and 309-2 may be configured to dynamically deflect an electron beam to scan a desired area on the surface of a sample 308. The dynamic deflection of an electron beam may cause a desired area or a desired region of interest to be scanned iteratively, for example in a raster scan pattern, to generate secondary electron beams (e.g., 236, 238, and 240 of FIG. 2A) for sample inspection. Deflectors 309-1 or 309-2 can be configured to deflect an electron beam in X-axis or Y-axis directions. As used herein, X-axis and Y-axis form Cartesian coordinates of an arbitrary reference frame, where the electron beam may propagate along a Z-axis or primary optical axis 304. The X-axis refers to the horizontal axis or the lateral axis extending along the width of the paper, and the Y-axis refers to the vertical axis extending in-and-out of the plane of the paper in the view of FIG. 2A, FIG. 2B, or FIG. 3A.

Reference is now made to FIG. 3B, which shows a representation of a charged particle beam passing through a deflector, consistent with embodiments of the present disclosure. In some embodiments, a charged particle beam may be deflected as it passes through a region between a pair of electrodes 335 and 345 of a deflector. As shown in FIG. 3B, a charged particle beam 320 may travel along an axis 350. Axis 350 may align with the Z-axis of a charged particle beam system. An electrode 335 and an electrode 345 may be disposed on either side of axis 350. Voltage may be applied to electrodes 335 and 345. Electric field may be formed between the electrodes, the components of the electric field being substantially perpendicular to the direction of travel of charged particle beam 320. As charged particle beam 320 travels through the resulting electric field, it may be influenced by the electric field. For example, its trajectory may be altered. A deflection scanning unit may use deflectors to deflect a beam so as to scan the beam across a region on a sample.

Reference is now made to FIG. 3C, which is a diagram illustrating a configuration of electrodes of a deflector, consistent with embodiments of the present disclosure. FIG. 3C shows a multi-pole structure with four electrodes e1-e4 that can be configured to function in different ways based on the voltages applied to each of the electrodes. A deflector (e.g., deflector 309-1 or 309-2 of FIG. 3A) may be formed using electrodes e1-e4. In some embodiments, a deflection voltage may be formed between opposing pairs of electrodes (e.g., the pair formed by electrodes e2 and e4; or the pair formed by electrodes e1 and e3). Multiple pairs of electrodes may be combined so that deflection in a two-dimensional plane is possible. For example, a first pair of electrodes (e.g., electrodes e2 and e4) can operate to deflect a beam in an x-direction and a second pair of electrodes (e.g., electrodes e1 and e3) can operate to deflect a beam in a y-direction. A deflector may be located in the region of an objective lens in a SEM system. The deflector may be used to dynamically direct a beam to a desired location on a sample surface. In some embodiments, there may be multiple beams that may be directed to multiple locations on the sample surface.

As illustrated in FIG. 3A, a deflection scanning unit can comprise two deflectors 309-1 and 309-2 that are stacked in a z-direction and are configured to cooperate with each other to precisely manipulate a beam. Because a minor error in one or both of the deflectors in this configuration could cause the trajectory of the beam to be deviated further from an intended trajectory, accurate and precise manipulation of deflectors is more critical. While a deflection scanning unit (e.g., deflection scanning unit 226 of FIG. 2A) or a deflector unit (e.g., deflector unit 132c of FIG. 2B) is illustrated to comprise two deflectors 309-1 and 309-2 each having four electrodes e1-e4, it should be noted that any number of deflectors with any number of electrodes may be used in embodiments of this disclosure, not limited to the configuration illustrated in FIGS. 3A-3C.

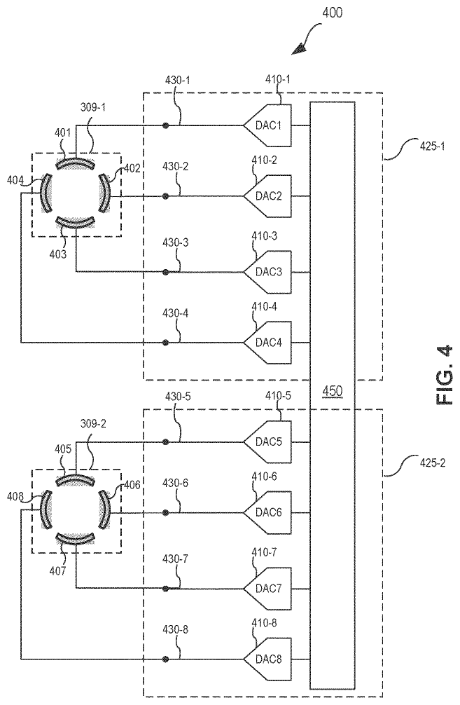

Reference is now made to FIG. 4, which illustrates an exemplary configuration of a deflection control unit 400 associated with charged-particle beam deflectors (e.g., primary electron beam deflectors 309-1 and 309-2), consistent with embodiments of the present disclosure. As illustrated, each primary electron beam deflector may be electronically driven by a corresponding driver system. As an example, deflection control unit 400 may comprise a driver system 425-1 associated with primary electron beam deflector 309-1, and a driver system 425-2 associated with primary electron beam deflector 309-2. As shown in FIG. 4, deflector 309-1 can be implemented to comprise four electrodes 401-404, and deflector 309-2 can be implemented to comprise four electrodes 405-408. Driver system 425-1 may comprise a scan control unit 450 and a digital-to-analog (DAC) converter 410. It is to be appreciated that although not illustrated, driver system 425-1 may include other components and circuitry such as variable gain amplifiers, power supplies, timing circuits, etc. as appropriately needed to manipulate primary electron beam traveling along primary optical axis (e.g., primary optical axis 304 of FIG. 3A). In some embodiments, driver system 425-1 may also include circuitry for calibration, offset and gain adjustments, scanning pattern generation, or diagnostics.

Scan control unit 450 may be configured to generate a deflection signal 430 configured to be applied to primary electron beam deflectors 309-1 and 309-2. Deflection signal 430 may comprise a voltage/current signal applied to a corresponding electrode of a primary electron beam deflector. In some embodiments, deflection control unit 400 may comprise a single scan control unit 450 configured to generate and to supply deflection signals for multiple driver systems (e.g., 425-1 and 425-2).

In some embodiments, driver system 425-1 may comprise circuitry such as digital-to-analog converter 410, configured to convert digital deflection signal 430 to an analog deflection signal. Driver system 425-1 may further comprise circuitry such as a variable gain amplifier (not shown), configured to receive the analog deflection signal and generate a tunable amplitude of the deflection signal. In general, variable gain amplifiers are signal-conditioning amplifiers with electronically settable voltage gain. A variable gain amplifier may comprise an analog VGA, or a digital VGA, or any suitable circuitry.

In some embodiments, scan control unit 450 can generate a plurality of deflection signals corresponding to a plurality of electrodes 401 to 408 of deflectors 309-1 and 309-2. As shown in FIG. 4, scan control unit 450 can generate eight deflection signals for manipulating electrodes 401-408 of deflectors 309-1 and 309-2. In some embodiments, deflection control unit 400 can comprise a plurality of DACs 410-1 to 410-8 to convert digital deflection signals 430-1 to 430-8 to analog deflection signals. It is illustrated in FIG. 4 that scan control unit 450 comprises eight DACs 410-1 to 410-8 corresponding to eight electrodes 401 to 408 of deflectors 309-1 and 309-2.

While FIG. 4 illustrates each deflector electrode (e.g., electrodes 401 to 408) is associated with an individual DAC (e.g., DACs 410-1 to 410-8), it will be appreciated that any configuration of deflector electrodes and DACs can be utilized in some embodiments of the present disclosure. In some embodiments, a pair of deflector electrodes (e.g., a first pair of electrodes 401 and 403 or a second pair of electrodes 402 and 404) can be configured to share two DACs in an alternative configuration. In this configuration, driver system 425-01 for controlling the pair of deflector electrodes (e.g., a first pair of electrodes 401 and 403) can further include an adder that receives analog outputs of the two DACs as input and outputs a superposition of the analog outputs of the two DACs according to a designed equation or relationship. In some embodiments, the adder can be a differential adder. The same absolute value of the output (V) of the adder can be applied to the pair of deflector electrodes (e.g., a first pair of electrodes 401 and 403) with opposite directions. For example, positive value +V can be applied to electrode 401 and negative value −V can be applied to electrode 403. In some embodiments, two different reference voltages can be applied to two DACs shared by the pair of electrodes (e.g., a first pair of electrodes 401 and 403). In some embodiments, a pair of electrodes can be controlled to deflect a beam in a predetermined direction. For example, a first pair of electrodes 401 and 403 can be controlled to deflect a beam in an X-direction and a second pair of electrodes 402 and 404 can be controlled to deflect a beam in a Y-direction. It will be noted that driver systems (e.g., driver system 425-1 or 425-2) for other pairs of electrodes (e.g., a second pair of electrodes 402 and 404, a third pair of electrodes 405 and 407, and a fourth pair of electrodes 406 and 408) can be similarly configured as the one described above (e.g., one adder shared by two DACs). While an alternative configuration of deflector electrodes and DACs is illustrated using a deflector (e.g., deflectors 309-1 and 309-2) having four deflector electrodes (i.e., a quadrupole structure), it will be appreciated that the alternative configuration can be applicable to any deflector having any multi-pole structure such as a dipole (2-pole) structure, an octupole (8-pole) structure, etc. In some embodiments using an octupole structure, a driver system can be configured that a pair of deflector electrodes among the eight deflector electrodes can share two DACs and one adder. In some embodiments using an octupole structure, a driver system can be configured that two pairs of deflector electrodes can share two DACs and one adder. The same absolute value of the output (V) of the adder can be applied to the two pairs of deflector electrodes. For example, positive value +V can be applied to a first pair of deflector electrodes and negative value −V can be applied to a second pair of deflector electrodes that are opposite to the first pair of deflector electrodes.

A digital-to-analog converter (e.g., DAC 410-1 to 410-8) is a device having various components such as transistors, resistors, wirings, etc. Due to the complexity and the need for precisely matched components, DACs (e.g., DACs 410-1 to 410-8) can be implemented as integrated circuits (ICs), e.g., in the form of IC chips that integrate analog/digital circuits therein. Errors in designing, or variances in manufacturing or fabricating a DAC may cause the DAC to output an analog value that is deviated from an intended analog value corresponding to a certain digital input. This may result in a beam scanning a wrong position on a sample and thus causes an error on a resultant inspection image. In some embodiments, a plurality of DACs in one inspection system (e.g., system 100 of FIG. 1 or beam tool 104A or 104B of FIG. 2A or 2B) can be implemented to have the same architecture and design. However, each DAC's behavior can differ from the other DACs due to manufacturing process variances. For example, DACs having the same design and architecture can output differing values from a same digital input depending on the corresponding process variances such as under-etching, over-etching, process errors, etc.

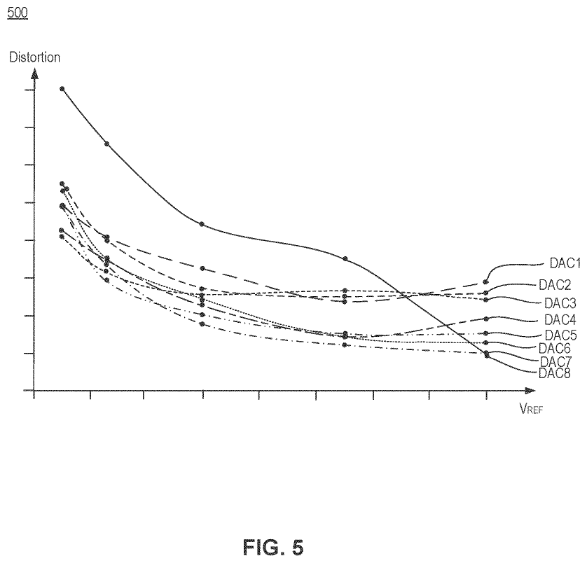

FIG. 5 is a graph 500 illustrating distortions introduced by DACs of a deflection control unit associated with charged-particle beam deflectors. In graph 500, an x-axis represents a reference voltage V_{REF} applied to DACs and a y-axis represents a distortion introduced by DACs. The reference voltage determines an output scale of a DAC and thus is linked to a scanning angle as well as a field of view (FOV) of a sample scanning. In this graph, a Gaussian distribution is used to quantify behavior of a distortion introduced by a DAC and the distortion is measured by a three-sigma value of the distribution. Graph 500 shows distortions of eight DACs, which constitutes one inspection system (e.g., EBI system 100 of FIG. 1 or beam tool 104A or 104B of FIG. 2A or 2B). As shown in FIG. 5, it is noted that DACs demonstrate different distortion behavior although eight DACs are from one inspection system. For example, DACs have different distortion values at the same reference voltage. Further, a distortion value of each DAC may change depending on a reference voltage applied to the corresponding DAC. It is also noted from FIG. 5 that DACs may demonstrate differing behavior and one DAC's behavior could change depending on its operating conditions such as a reference voltage. While FIG. 5 illustrates a reference voltage as a factor contributing to distortion behavior of DACs, it will be appreciated that DACs' distortion behavior can be sensitive to other factors such as a temperature, etc.

In order to correct or calibrate errors introduced by DACs associated with deflectors of a SEM tool, various efforts have been made. First, a linear calibration method has been applied to correct error(s) of DACs. The linear calibration method comprises a gain or offset calibration through a digital circuit or an analog circuit. In some instances, the linear calibration can be performed either via hardware or software. However, the linear calibration may correct linear errors caused by DACs but does not correct non-linear distortions introduced by DACs. As shown in FIG. 5, distortions caused by DACs show substantial non-linearity characteristics. Therefore, the error correcting performance of the linear calibration method may be limited as this method only addresses linear distortions.

In order to correct non-linearity errors caused by DACs, an error correction method based on an inspection image has been conventionally utilized. In the error correction method based on an inspection image, the inspection image is compared to a reference image. The reference image can be a layout file for a wafer design corresponding to the inspection image. When there is a mismatch between the reference image and the inspection image, it can be presumed that the mismatch originates from DACs errors. Thereby, the inspection image-based correction method calibrates digital inputs to the DACs to correct the error (e.g., to remove the mismatch) on an inspection image going forward. For example, an inspection image may have a wavy line while a reference image indicates a straight line on the same location. In the inspection image-based correction method, it is presumed that the wavy line is an error introduced by the DACs, and then inputs to DACs are adjusted such that an inspection image can have a straight line to match the reference image going forward. However, it has been reported that the inspection image-based error correction method often suffers from over corrections by calibrating deflection inputs to the DACs even when the error(s) on the inspection image does not originate from errors on the DACs. For example, an inspection image may have a wavy line while a reference image indicates a straight line because the sample, i.e., a wafer itself is structured to have a wavy line instead of a straight line. In this case, while the wavy line on the inspection image is not an error on the inspection image originating from the DACs, the inspection image-based correction methods may calibrate the deflection inputs to the DACs to have a straight line instead of the wavy line. Because this wavy line is not an error on an inspection image but an error on the wafer itself, the deflection input calibrations may cause more errors on an inspection image due to the overcorrection. Further, although the inspection image-based error correction method can contribute to non-linearity error corrections, the method only applies to calibrations generic to all DACs of one inspection system. In other words, the conventional method could not address error(s) specific to each DAC. As the inspection image-based calibration is performed per hardware design/setting, the time-consuming calibration process repeats for all use cases (e.g., separate calibration for each hardware design/setting), which wastes resources of the inspection system and degrades inefficiency. Moreover, as mentioned above, calibration of the conventional error correction method is performed after an inspection image is generated using the inspection system with DACs because the calibration is based on a comparison between the inspection image and a reference image, which requires longer initialization time and thus worsens resource waste of the inspection system.

The conventional method could meet the industry accuracy criteria in the past. However, the demand for more accurate inspection systems is ever increasing as the physical sizes of IC components continue to shrink and defect detection accuracy becomes more important. Therefore, methods and systems that can more accurately and precisely manipulate deflectors are thus desired.

According to some embodiments of the present disclosure, each DAC's behavior can be individually characterized, and a lookup table for each DAC can be established. According to some embodiments, a lookup table for each DAC can be utilized to control deflectors. According to some embodiments of the present disclosure, calibration to each DAC can be performed before the inspection system is launched for inspection, and thus resource waste can be avoided.

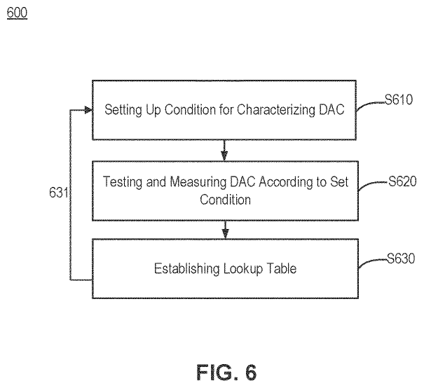

FIG. 6 is a flow chart illustrating an exemplary method for generating a lookup table for characterizing a DAC of a deflection control unit associated with charged-particle beam deflectors, consistent with embodiments of the present disclosure. In some embodiments, the steps of method 600 can be performed during a manufacturing process of an inspection system (e.g., EBI system 100 of FIG. 1 or beam tool 104A or 104B of FIG. 2A or 2B) with an automatic test fixture, digital processor (e.g., FPGA), and a multimeter. The steps of method 600 can be performed using the features of a computing device, e.g., controller 109 of FIG. 1. It is appreciated that the illustrated method 600 can be altered to modify the order of steps and to include additional steps.

In step S610, a condition for characterizing a DAC is set up. According to some embodiments, a condition(s) can be factor(s) that contribute to distortion behavior of a DAC. For example, a condition can comprise a reference voltage applied to a DAC, a temperature at which a DAC is to be tested and measured, etc. In some embodiments, a condition can be a set of conditions at which a DAC is to be tested and measured. In some embodiments, a condition for characterizing a DAC can comprise a first reference voltage 1^{st} V_{REF}. In some embodiments, a condition for characterizing a DAC can comprise other factors to which DAC's behavior is sensitive.

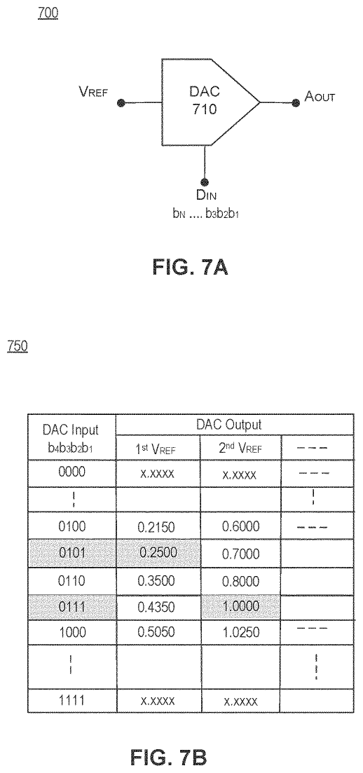

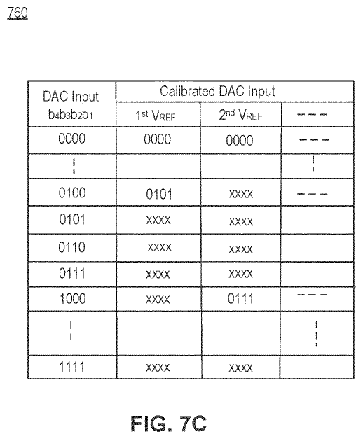

In step S620, a DAC is tested and measured according to a set condition(s) in step S610. In some embodiments, all digital input values are input to a DAC and an analog output of the DAC is measured under the set condition(s). FIG. 7A is a schematic diagram illustrating a test environment for characterizing a DAC, consistent with embodiments of the present disclosure. As shown in FIG. 7A, a DAC 710 is to be tested and measured under a condition(s) set in step S610. In some embodiments, a first reference voltage 1^{st} V_{REF} is set as reference voltage V_{REF} of DAC 710. In some embodiments, an analog output A_{OUT} of DAC 710 is measured for a digital input D_{IN} of DAC 710 under the condition(s) set in step S610. According to some embodiments of the present disclosure, analog output A_{OUT} is measured for all possible digital inputs D_{IN} of DAC 710 under the condition(s).

As shown in FIG. 7A, digital input D_{IN} can be N-bit digital input as b_{N} . . . b₃b₂b₁ where b₁ represents a least significant bit and by represent a most significant bit. In some embodiments, analog output A_{OUT} of DAC 710 is measured for all possible digital input D_{IN}. For example, analog output A_{OUT} of DAC 710 is measured by changing N-bit digital input from 0 . . . 000 to 1 . . . 111. Reference voltage V_{REF} applied to DAC 710 changes a scale of analog output A_{OUT} of DAC 710 corresponding to N-bit digital input D_{IN}. In some embodiments, a maximum output of DAC 710 can be determined by reference voltage V_{REF} applied to DAC 710. For example, the maximum output value of analog output A_{OUT} can be determined as Vₘₐₓ=((2^{N}−1)/2^{N})*V_{REF}, where a step size equals to V_{REF}/2^{N}.

Referring back to FIG. 6, a lookup table for a DAC is established in step S630. According to some embodiments of the present disclosure, a lookup table for a DAC can be established according to the test and measurement in step S620. FIG. 7B is an example lookup table 750 characterizing behavior of a DAC of a deflection control unit, consistent with embodiments of the present disclosure. As shown in FIG. 7B, DAC's outputs to all possible digital inputs are recorded in lookup datable 750. While FIG. 7B describes digital input D_{IN} as 4-digit input b₄b₃b₂b₁ for illustration purposes, it will be appreciated that any number of digital inputs can be utilized in some embodiments of the present disclosure. As shown in a first column and a second column of FIG. 7B, analog output A_{OUT} of DAC 710 is measured and recorded for all possible digital input D_{IN} from 0000 to 1111. In FIG. 7B, 1^{st} V_{REF} is set for 1V as an example. As known from output values of DAC 710 in FIG. 7B, DAC 710 outputs an analog value that is deviated from an intended analog output of DAC 710. For example, while DAC 710 is designed to output 0.2500 when reference voltage 1V and digital input 0100 are applied to DAC 710, DAC 710 outputs 0.2150 during the test. Such deviations may be caused from error(s) on a DAC. As such, table 750 can characterize DAC's behavior under a certain set of condition(s) by recording actual outputs of DAC 710 corresponding to the digital inputs.

As shown in an arrow 631, once lookup table 750 is established for a first set of condition(s), steps S610 to S630 can repeat for a second set of condition(s). In some embodiments, a second set of condition(s) can include a second reference voltage 2^{nd} V_{REF} applied to a DAC. As shown in a first column and a third column of FIG. 7B, analog output A_{OUT} of DAC 710 is measured and recorded for all possible digital input D_{IN} from 0000 to 1111. In FIG. 7B, 2^{nd} V_{REF} is set for 2V as an example. As known from output values of DAC 710 in FIG. 7B, DAC 710 may output an analog value that is deviated from an intended analog output of DAC 710. For example, while DAC 710 is designed to output 1.000 when reference voltage 2V and digital input 1000 are applied to DAC 710, DAC 710 outputs 1.0250 during the test. It will be appreciated that a lookup table establishing process can repeat any number of times to fully characterize behavior of DAC 710 for various conditions.

It will be appreciated that a plurality of tables can be established for a plurality of conditions while one table 750 is established for two different conditions in FIG. 7B. While a process for generating a lookup table for one DAC has been illustrated, it will be appreciated that a SEM tool can have a plurality of DACs and table 750 of FIG. 7B can be established for each DAC of a SEM tool. It will be appreciated that FIG. 7B describes table 750 for illustration purposes and a different format of lookup table(s) can be utilized. FIG. 7C describes another example lookup table characterizing a DAC of a deflection control unit, consistent with embodiments of the present disclosure. In some embodiments, a lookup table 760 can be established to build relationships between all possible digital inputs and calibrated DAC input values without having analog outputs. As shown in FIG. 7C, table 760 includes calibrated DAC inputs in second and third columns for a corresponding DAC digital input. Referring back to FIG. 7B, while DAC 710 is designed to output 0.2500 when reference voltage 1V and digital input 0100 are applied to DAC 710, DAC 710 outputs 0.2500 when digital input 0101 is applied. Accordingly, digital input 0101 can be a calibrated input for digital input 0100 for first reference voltage 1^{st} V_{REF}. Thus, lookup table 760 of FIG. 7C can list digital value 0101 as a calibrated DAC input for DAC input 0100 in second column. Similarly, while DAC 710 is designed to output 1.0000 when reference voltage 2V and digital input 1000 are applied to DAC 710, DAC 710 outputs 1.0000 when digital input 0111 is applied. Accordingly, digital input 0111 can be a calibrated input for digital input 1000 for second reference voltage 2^{nd} V_{REF}. Thus, lookup table 760 of FIG. 7C can list digital value 0111 as a calibrated DAC input for DAC input 1000 in third column.

According to some embodiments of the present disclosure, a lookup table(s) for characterizing each DAC of an inspection system can be established. According to some embodiments of the present disclosure, a lookup table that associates digital inputs with actual analog outputs of a DAC corresponding to the digital inputs can be provided. According to some embodiments of the present disclosure, lookup tables (e.g., table 750 or table 760) for characterizing a plurality of DACs can be stored in a memory (e.g., a flash memory) that can be mounted on the same printed circuit board (PCB) on which DACs are assembled. According to some embodiments of the present disclosure, lookup tables for DACs can be referred to when manipulating deflectors of an inspection system. According to some embodiments of the present disclosure, a digital input to generate a target analog signal for manipulating a corresponding deflector electrode by an associated DAC can be determined based on a pre-established lookup table for the associated DAC. According to some embodiments of the present disclosure, an inspection system can be equipped with sensors to monitor operation conditions under which the DACS of the inspection system operate. For example, an inspection system can be equipped with a temperature sensor to monitor a temperature close to the DACs such that the temperature could be utilized as a factor contributing to distortion behavior of the corresponding DAC. In some embodiments, other sensors that can monitor factors contributing to distortion behavior of DACs can also be provided.

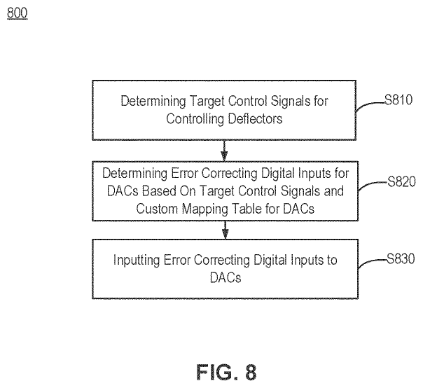

FIG. 8 is a flow chart illustrating an exemplary method for controlling deflectors of an inspection system, consistent with embodiments of the present disclosure. The steps of method 800 can be performed using the features of a computing device, e.g., controller 109 of FIG. 1. In some embodiments of the present disclosure, the steps of method 800 can be performed by a scan control unit 450 of FIG. 4. In some embodiments, scan control unit 450 can perform the steps of method 800 according to user settings for operating deflector(s) provided by a host computer of the system. In some embodiments, the steps of method 800 can be performed by digital processor (e.g., FPGA). It is appreciated that the illustrated method 800 can be altered to modify the order of steps and to include additional steps.

In step S810, a target control signal for controlling a deflector electrode can be determined. Step S810 can be performed, for example, a scan control system 450 of FIG. 4, among others. In some embodiments, a target control signal for controlling a deflector electrode (e.g., electrodes 401-408 of FIG. 4) can be determined so that a primary particle beam (e.g., a primary charged-particle beam 210 of FIG. 2A) can be incident on a sample at a targeted position. In some embodiments, target control signals for controlling deflector electrodes 401-408 can be determined.

In step S820, an error correcting digital input for a DAC corresponding to a deflector electrode can be determined based on the determined target control signal and a lookup table characterizing behavior of the DAC. Step S820 can be performed, for example, a scan control system 450 of FIG. 4, among others. In some embodiments, scan control system 450 can determine which lookup table to refer to based on a set of condition(s) under which the DAC operates. For example, a plurality of lookup tables (e.g., table 750 or table 760) have been established for a DAC (e.g., DAC 410-1) corresponding to a deflector electrode (e.g., electrode 401) using differing sets of condition(s). Scan control system 450 can select, among the plurality of lookup tables, a certain table that is established with the same condition(s) of the current inspection system operation conditions.

When a DAC (e.g., DAC 410-1) operates at first reference voltage 1^{st} V_{REF} in the current inspection system, a table in second column of FIG. 7B or FIG. 7C can be selected to be utilized when determining an error correcting digital input to the DAC. As an example, it is assumed that a target control signal is 0.2500. Scan control system 450 can determine an error correcting digital input for the DAC to generate the target control signal of 0.2500 referring to the table in the second column of FIG. 7B or FIG. 7C. As indicated in grey color in FIG. 7B, it can be determined that the DAC generates analog output 0.2500 when digital input 0101 is inputted to the DAC with 1^{st} V_{REF}. In this example, an error correcting digital input corresponding to the target control signal 0.2500 is determined to be digital code 0101. From FIG. 7C, an error correcting digital input for obtaining target control signal 0.2500 can be determined to be a calibrated DAC input (i.e., 0101) corresponding to digital input 0100 that is designed to output control signal 0.2500 when there is no error. Similarly, when a DAC operates at second reference voltage 2^{nd} V_{REF}, scan control system 450 can determine that the second table, which is in the third column of FIG. 7B, to be referred to when determining an error correcting digital input. As an example, it is assumed that a target control signal is 1.0000. Scan control system 450 can determine an error correcting digital input for the DAC to generate the target control signal of 1.0000 referring to the second table of FIG. 7B. As indicated in grey color in FIG. 7B, it can be determined that the DAC generates analog output 1.0000 when digital input 0111 is inputted to the DAC. In this example, an error correcting digital input corresponding to the target control signal 1.0000 is determined to be digital code 0111. From FIG. 7C, an error correcting digital input for obtaining target control signal 1.0000 can be determined to be a calibrated DAC input (i.e., 0111) corresponding to digital input 1000 that is designed to output control signal 1.0000 when there is no error.

As noted from FIG. 7B, table 750 may not provide an analog output matching the target control signal because the digital inputs are discrete and there is a step size. Therefore, in some embodiments, scan control system 450 can determine an error correcting digital input that is associated with the closest analog output to the target control signal. Therefore, when the error correcting digital input is inputted to the DAC, the DAC can generate an output that compensate the error caused by the DAC or at least reduce the error caused by the DAC.

In some embodiments, error correcting digital inputs for a plurality of DACs (e.g., DACs 410-1 to 410-8) can be determined to compensate errors caused by corresponding DACs while providing target control signals to manipulate corresponding deflector electrodes (e.g., electrodes 401-408). It will be appreciated that error correcting digital inputs for each DAC can be determined according to its own target control signal and a lookup table customized for its corresponding DAC. It will be appreciated that error correcting digital inputs for multiple DACs can be differing from each other even when the target control signal is the same for the multiple DACs because each error correcting digital input is determined referring to a table customized to be specific to an associated DAC.

In step S830, an error correcting digital input for a DAC can be inputted to a corresponding DAC. Step S830 can be performed, for example, a scan control system 450 of FIG. 4, among others. In some embodiments, an error correcting digital input, which is determined in step S820, can be inputted to a corresponding DAC (e.g., DAC 410-1) such that the DAC can generate a target control signal determined in step S810. Similarly, error correcting digital inputs for a plurality of DACs (e.g., DACs 410-1 to 410-8) can be inputted to the plurality of DACs to compensate errors caused by corresponding DACs while providing target control signals to manipulate corresponding deflector electrodes (e.g., electrodes 401-408). In some embodiments, DACs can generate target control signals by receiving error correcting digital inputs that are determined in step S820.

A non-transitory computer readable medium may be provided that stores instructions for a processor of a controller (e.g., controller 109 of FIG. 1) to carry out, among other things, image inspection, image acquisition, stage positioning, beam focusing, electric field adjustment, beam bending, condenser lens adjusting, activating charged-particle source, beam deflecting, and methods 600 and 800. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method for controlling deflectors of a charged-particle inspection system, the method comprising:
establishing a mapping relationship for each digital-to-analog converter (DAC) of a plurality of DACs included in a charged-particle inspection system, the mapping relationship characterizing non-linearity behavior of each of the DACs;
determining target control signals for manipulating deflectors of the charged-particle inspection system;
determining, for each DAC of the plurality of DACs, an error correcting digital input based on a corresponding target control signal among the target control signals and the corresponding mapping relationship; and
inputting the corresponding error correcting digital input to the each DAC to enable the each DAC to generate a corresponding error compensated output.
2. The method of clause 1, wherein inputting the corresponding error correcting digital input to the each DAC comprises:
inputting a first error correcting digital input to a first DAC of the plurality of DACs and a second error correcting digital input, which is different from the first error correcting digital input, to a second DAC of the plurality of DACs.
3. The method of clause 1 or 2, wherein establishing the mapping relationship comprises:
setting up a condition for charactering each of the DACs;
measuring analog outputs of each of the DACs corresponding to all digital inputs under the set condition; and
establishing the mapping relationship associating the digital inputs with the measured analog outputs of each of the DACs.
4. The method of clause 1 or 2, wherein establishing the mapping relationship comprises:
establishing a plurality of mapping tables for a plurality of conditions under which the charged-particle inspection system operates.
5. The method of clause 4, wherein the plurality of conditions includes a reference voltage or a temperature.
6. The method of any one of clauses 1 to 5, further comprising:
manipulating the deflectors based on the generated error compensated output by each of the DACs.
7. The method of any one of clauses 1 to 6, wherein the mapping relationship includes a mapping table.
8. A method for controlling deflectors of a charged-particle inspection system, the method comprising:
determining target control signals for manipulating a plurality of deflector electrodes, the plurality of deflector electrodes associated with a plurality of DACs;
determining, for each DAC of the plurality of DACs, an error correcting digital input based on a corresponding target control signal among the target control signals and a corresponding mapping relationship among a plurality of mapping relationships each representing non-linearity behavior of each of the DACs; and
inputting the corresponding error correcting digital input to the each DAC to enable the each DAC to generate a corresponding error compensated output.
9. The method of clause 8, wherein inputting the corresponding error correcting digital input to the each DAC comprises:
inputting a first error correcting digital input to a first DAC of the plurality of DACs and a second error correcting digital input, which is different from the first error correcting digital input, to a second DAC of the plurality of DACs.
10. The method of clause 8 or 9, wherein the plurality of mapping relationships are established by:
setting up a condition for charactering each of the DACs;
measuring analog outputs of each of the DACs corresponding to all digital inputs under the set condition; and
establishing the mapping relationship associating the digital inputs with the measured analog outputs of each of the DACs.
11. The method of clause 10, wherein the condition includes a reference voltage or a temperature.
12. The method of any one of clauses 8 to 10, further comprising:
manipulating the deflectors based on the generated error compensated output by the each DAC.
13. A charged-particle inspection apparatus, comprising:
a charged-particle beam source configured to generate a primary charged-particle beam for sample scanning;
a plurality of deflector electrodes configured to influence the charged particle beam; and
a controller configured to control the plurality of deflector electrodes, wherein the controller is configured to perform:
determining target control signals for controlling the plurality of deflector electrodes, the plurality of deflector electrodes associated with a plurality of DACs;
determining, for each DAC of the plurality of DACs, an error correcting digital input based on a corresponding target control signal among the target control signals and a corresponding mapping relationship among a plurality of mapping relationships each representing non-linearity behavior of each of the DACs; and
inputting the corresponding error correcting digital input to the each DAC to enable the each DAC to generate a corresponding error compensated output.
14. The apparatus of clause 13, wherein inputting the corresponding error correcting digital input to the each DAC comprises:
inputting a first error correcting digital input to a first DAC of the plurality of DACs and a second error correcting digital input, which is different from the first error correcting digital input, to a second DAC of the plurality of DACs.
15. The apparatus of clause 13 or 14, wherein the plurality of mapping relationships are established by:
setting up a condition for charactering each of the DACs;
measuring analog outputs of each of the DACs corresponding to all digital inputs under the set condition; and
establishing the mapping relationship associating the digital inputs with the measured analog outputs of each of the DACs.
16. The apparatus of clause 15, wherein the condition includes a reference voltage or a temperature.
17. The apparatus of any one of clauses 13 to 16, wherein the controller is configured to further perform:
controlling the deflector electrodes based on the generated error compensated output by the each DAC.
18. A non-transitory computer readable medium including a set of instructions that is executable by one or more processors of a controller to cause the controller to perform a method for controlling deflectors of a charged-particle inspection system, the method comprising:
determining target control signals for manipulating a plurality of deflector electrodes, the plurality of deflector electrodes associated with a plurality of DACs;
determining, for each DAC of the plurality of DACs, an error correcting digital input based on a corresponding target control signal among the target control signals and a corresponding mapping relationship among a plurality of mapping relationships each representing non-linearity behavior of each of the DACs; and
inputting the corresponding error correcting digital input to the each DAC to enable the each DAC to generate a corresponding error compensated output.
19. The computer readable medium of clause 18, wherein, in inputting the corresponding error correcting digital input to the each DAC, the set of instructions that is executable by the one or more processors of the controller to cause the controller to further perform:
inputting a first error correcting digital input to a first DAC of the plurality of DACs and a second error correcting digital input, which is different from the first error correcting digital input, to a second DAC of the plurality of DACs.
20. The computer readable medium of clause 18 or 19, wherein the plurality of mapping relationships are established by:
setting up a condition for charactering each of the DACs;
measuring analog outputs of each of the DACs corresponding to all digital inputs under the set condition; and
establishing the mapping relationship associating the digital inputs with the measured analog outputs of each of the DACs.
21. The computer readable medium of clause 20, wherein the condition includes a reference voltage or a temperature.
22. The computer readable medium of clause 20, wherein the set of instructions that is executable by the one or more processors of the controller to cause the controller to further perform: manipulating the deflectors based on the generated error compensated output by the each DAC.
23. A method for establishing mapping relationships for a plurality of DACs of a charged-particle inspection system, the method comprising:
setting up a condition for charactering each DAC of the plurality of DACs, the plurality of DACs associated with a plurality of deflector electrodes of the charged-particle inspection system;
measuring analog outputs of each of the DACs corresponding to all digital inputs under the set condition; and
establishing a mapping relationship associating the digital inputs with the measured analog outputs of each of the DACs.
24. The method of clause 23, wherein the condition includes a reference voltage or a temperature.
25. The method of clause 23 or 24, wherein the mapping relationship characterizing non-linearity behavior of each of the DACs.
25. An apparatus, comprising:
a memory having a plurality of mapping relationships for a plurality of DACs included in a charged-particle inspection system, each of the plurality of mapping relationships characterizing non-linearity behavior of each of the plurality of DACs;
at least one processor configured to execute a set of instructions to cause the apparatus to perform:
determining target control signals for manipulating a plurality of deflector electrodes, the plurality of deflector electrodes associated with the plurality of DACs; and
determining, for each DAC of the plurality of DACs, an error correcting digital input based on a corresponding target control signal among the target control signals and a corresponding mapping relationship among the plurality of mapping relationships,
wherein inputting the corresponding error correcting digital input to the each DAC enables the each DAC to generate a corresponding error compensated output.
26. The apparatus of clause 25, wherein the corresponding error correcting digital input to a first DAC of the plurality of DACs is different from the corresponding error correcting digital input to a second DAC of the plurality of DACs.
27. The apparatus of clause 25 or 26, wherein the plurality of mapping relationships are established by:
setting up a condition for charactering each of the DACs;
measuring analog outputs of each of the DACs corresponding to all digital inputs under the set condition; and
establishing the mapping relationship associating the digital inputs with the measured analog outputs of each of the DACs.
28. The apparatus of clause 27, wherein the condition includes a reference voltage or a temperature.
29. The apparatus of any one of clauses 25 to 28, wherein the at least one processor configured to execute the set of instructions to cause the apparatus to further perform:
controlling the deflector electrodes based on the generated error compensated output by the each DAC.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method for controlling deflectors of a charged-particle inspection system, the method comprising:
establishing a mapping relationship for each digital-to-analog converter (DAC) of a plurality of DACs included in a charged-particle inspection system, the mapping relationship characterizing non-linearity behavior of each of the DACs;
determining target control signals for manipulating deflectors of the charged-particle inspection system;
determining, for each DAC of the plurality of DACs, an error correcting digital input based on a corresponding target control signal among the target control signals and the corresponding mapping relationship; and
inputting the corresponding error correcting digital input to the each DAC to enable the each DAC to generate a corresponding error compensated output.

2. The method of claim 1, wherein inputting the corresponding error correcting digital input to the each DAC comprises:
inputting a first error correcting digital input to a first DAC of the plurality of DACs and a second error correcting digital input, which is different from the first error correcting digital input, to a second DAC of the plurality of DACs.

3. The method of claim 1, wherein establishing the mapping relationship comprises:
setting up a condition for charactering each of the DACs;
measuring analog outputs of each of the DACs corresponding to all digital inputs under the set condition; and
establishing the mapping relationship associating the digital inputs with the measured analog outputs of each of the DACs.

4. The method of claim 1, wherein establishing the mapping relationship comprises:
establishing a plurality of mapping tables for a plurality of conditions under which the charged-particle inspection system operates.

5. The method of claim 4, wherein the plurality of conditions includes a reference voltage or a temperature.

6. A charged-particle inspection apparatus, comprising:
a charged-particle beam source configured to generate a primary charged-particle beam for sample scanning;
a plurality of deflector electrodes configured to influence the charged particle beam; and
a controller configured to control the plurality of deflector electrodes, wherein the controller is configured to perform:
determining target control signals for controlling the plurality of deflector electrodes, the plurality of deflector electrodes associated with a plurality of DACs;
determining, for each DAC of the plurality of DACs, an error correcting digital input based on a corresponding target control signal among the target control signals and a corresponding mapping relationship among a plurality of mapping relationships each representing non-linearity behavior of each of the DACs; and
inputting the corresponding error correcting digital input to the each DAC to enable the each DAC to generate a corresponding error compensated output.

7. The apparatus of claim 6, wherein inputting the corresponding error correcting digital input to the each DAC comprises:
inputting a first error correcting digital input to a first DAC of the plurality of DACs and a second error correcting digital input, which is different from the first error correcting digital input, to a second DAC of the plurality of DACs.

8. The apparatus of claim 6, wherein the plurality of mapping relationships are established by:
setting up a condition for charactering each of the DACs;
measuring analog outputs of each of the DACs corresponding to all digital inputs under the set condition; and
establishing the mapping relationship associating the digital inputs with the measured analog outputs of each of the DACs.

9. The apparatus of claim 8, wherein the condition includes a reference voltage or a temperature.

10. The apparatus of claim 6, wherein the controller is configured to further perform:
controlling the deflector electrodes based on the generated error compensated output by the each DAC.

11. A non-transitory computer readable medium including a set of instructions that is executable by one or more processors of a controller to cause the controller to perform a method for controlling deflectors of a charged-particle inspection system, the method comprising:
determining target control signals for manipulating a plurality of deflector electrodes, the plurality of deflector electrodes associated with a plurality of DACs;
determining, for each DAC of the plurality of DACs, an error correcting digital input based on a corresponding target control signal among the target control signals and a corresponding mapping relationship among a plurality of mapping relationships each representing non-linearity behavior of each of the DACs; and
inputting the corresponding error correcting digital input to the each DAC to enable the each DAC to generate a corresponding error compensated output.

12. The computer readable medium of claim 11, wherein, in inputting the corresponding error correcting digital input to the each DAC, the set of instructions that is executable by the one or more processors of the controller to cause the controller to further perform:
inputting a first error correcting digital input to a first DAC of the plurality of DACs and a second error correcting digital input, which is different from the first error correcting digital input, to a second DAC of the plurality of DACs.

13. The computer readable medium of claim 11, wherein the plurality of mapping relationships are established by:
setting up a condition for charactering each of the DACs;
measuring analog outputs of each of the DACs corresponding to all digital inputs under the set condition; and
establishing the mapping relationship associating the digital inputs with the measured analog outputs of each of the DACs.

14. The computer readable medium of claim 13, wherein the condition includes a reference voltage or a temperature.

15. The computer readable medium of claim 13, wherein the set of instructions that is executable by the one or more processors of the controller to cause the controller to further perform:
manipulating the deflectors based on the generated error compensated output by the each DAC.
